(19) United States
(12) Patent Application Publication
(10) Pub. No.: US 2009/0236647 A1
(43) Pub. Date: Sep. 24, 2009

(54) SEMICONDUCTOR DEVICE WITH CAPACITOR

(75) Inventors: Hans-Joachim Barth, Muenchen (DE); Helmut Tews, Muenchen (DE)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Neubiberg (DE)

(21) Appl. No.: 12/050,192

(22) Filed: Mar. 18, 2008

(51) Int. Cl. H01L 29/00; H01L 21/00

(52) U.S. Cl. 257/296; 438/113; 257/E29.001; 257/E21.001

(57) ABSTRACT

An embodiment of the invention is a semiconductor structure, comprising: a semiconductor chip at least partially embedded within a support; and a capacitor disposed outside the lateral boundary of the chip, the capacitor electrically coupled to the chip.

### FIELD OF THE INVENTION

Generally, the present invention relates to semiconductor devices. More particularly, the present invention relates to semiconductor devices utilizing a capacitor.

### BACKGROUND OF THE INVENTION

Capacitors which are part of a semiconductor device, such as metal-insulator-metal or MIM capacitors, may require extra processing. An MIM capacitor may be formed as two metal layers with an embedded dielectric layer and this may be processed in addition to the back end of line metal stack. This extra processing may generate extra cost for metal deposition, lithography, and etch. In addition, the quality or Q factor for the capacitor may be low due to high ohmic resistances in the capacitor plates. New methods for making capacitors are needed.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become clear better understood by reference to the following detailed description. The elements of the drawings are not necessarily to scale relative to each other.

FIGS. 1A and 1B show an embodiment of a semiconductor chip;

FIGS. 2A through 2D show an embodiment of a plate assembly;

FIG. 3A shows a top view of an embodiment of a reconfiguration wafer;

FIG. 3B shows a top view of an embodiment of a reconfiguration wafer showing the fan-out region;

FIG. 3C shows a cross sectional view of an embodiment of a reconfiguration wafer showing the fan-out region;

FIG. 4A shows a top view of an embodiment of a semiconductor structure comprising a chip and a plate assembly;

FIG. 4B shows a cross sectional view of an embodiment of a semiconductor structure comprising a chip and a plate assembly;

FIG. 4C shows a cross sectional view of an embodiment of a semiconductor structure comprising a chip and a plate assembly;

FIG. 4D shows a top view of an embodiment of a semiconductor structure showing the fan-out region;

FIG. 4E shows a cross sectional view of a semiconductor structure showing the fan-out region;

FIG. 5A shows a top view of an embodiment of a semiconductor structure;

FIG. 5B shows a cross sectional view of an embodiment of a semiconductor structure;

FIG. 5C shows a cross sectional view of an embodiment of a semiconductor structure;

FIG. 5D shows a top view of an embodiment of a semiconductor structure showing the fan-out region;

FIG. 5E shows a cross sectional view of an embodiment of a semiconductor structure showing the fan-out region;

FIG. 6A shows a cross sectional view of an embodiment of a semiconductor structure; and

FIG. 6B shows a cross sectional view of an embodiment of a semiconductor structure;

FIG. 7A shows a cross sectional view of an embodiment of a semiconductor structure; and

FIG. 7B shows a cross sectional view of an embodiment of a semiconductor structure;

FIG. 8A shows a top view of an embodiment of a semiconductor structure; and

FIG. 8B shows a cross sectional view of an embodiment of a plate assembly; and

FIG. 8C shows a top view of an embodiment of a semiconductor structure.

### DETAILED DESCRIPTION OF THE INVENTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

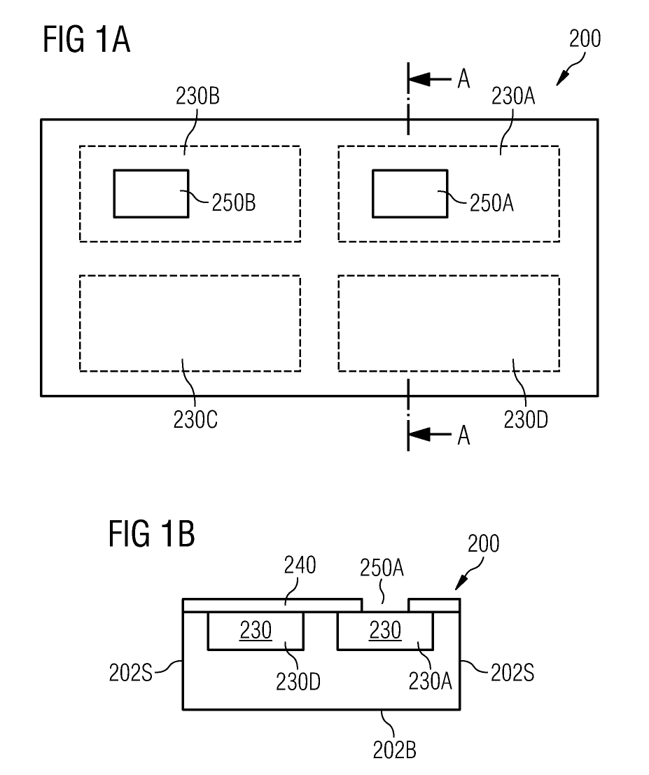

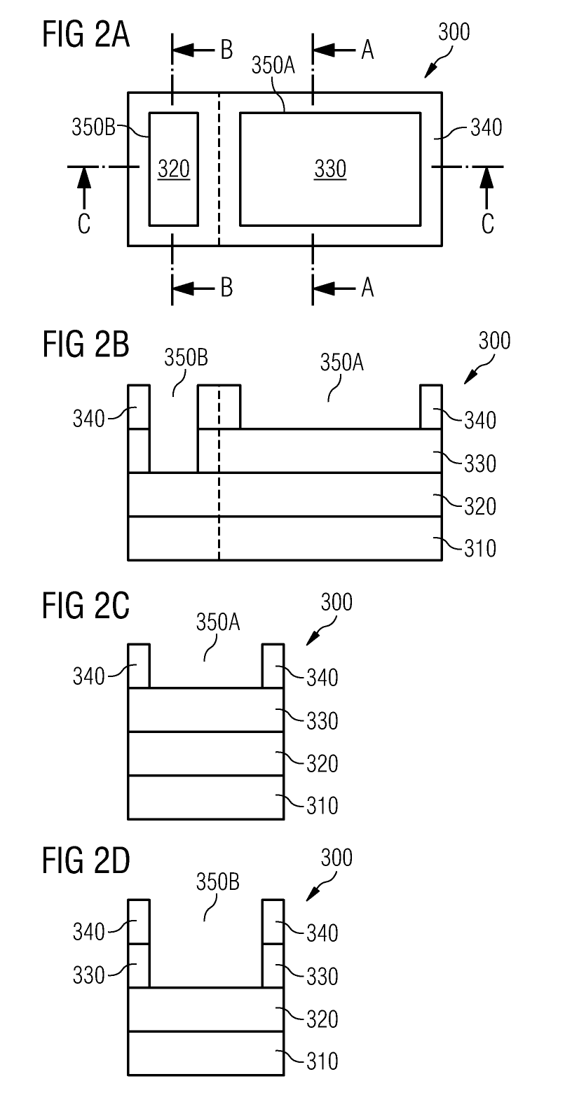

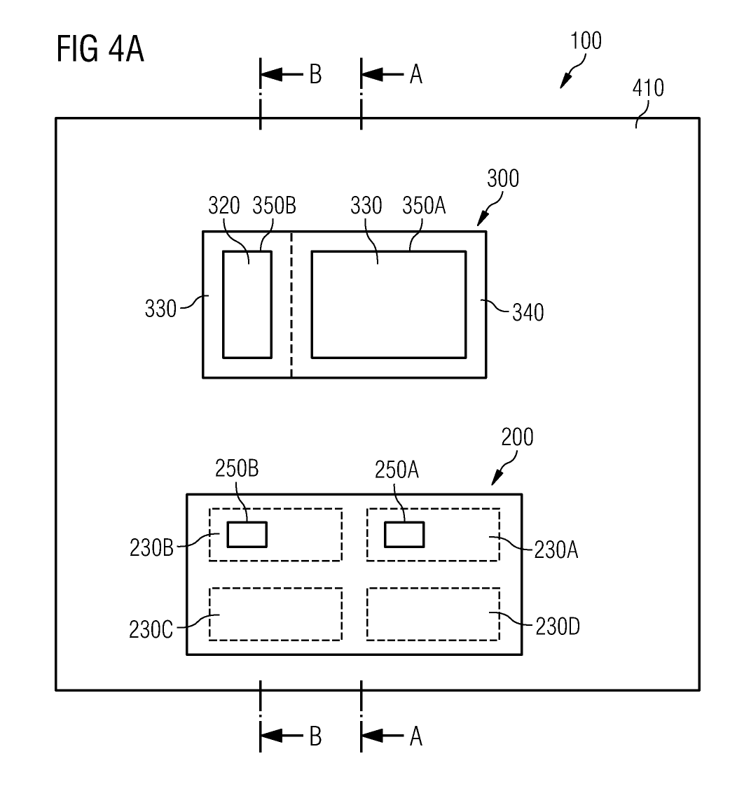

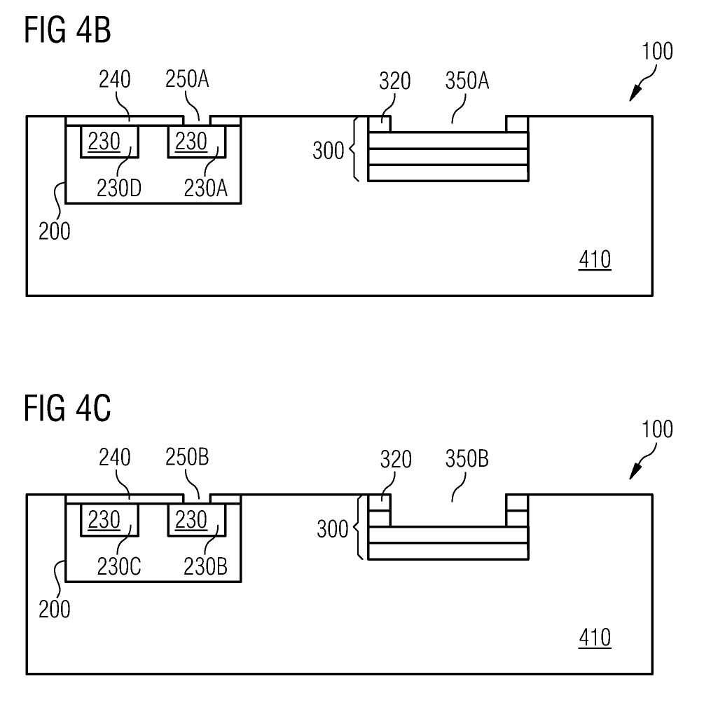

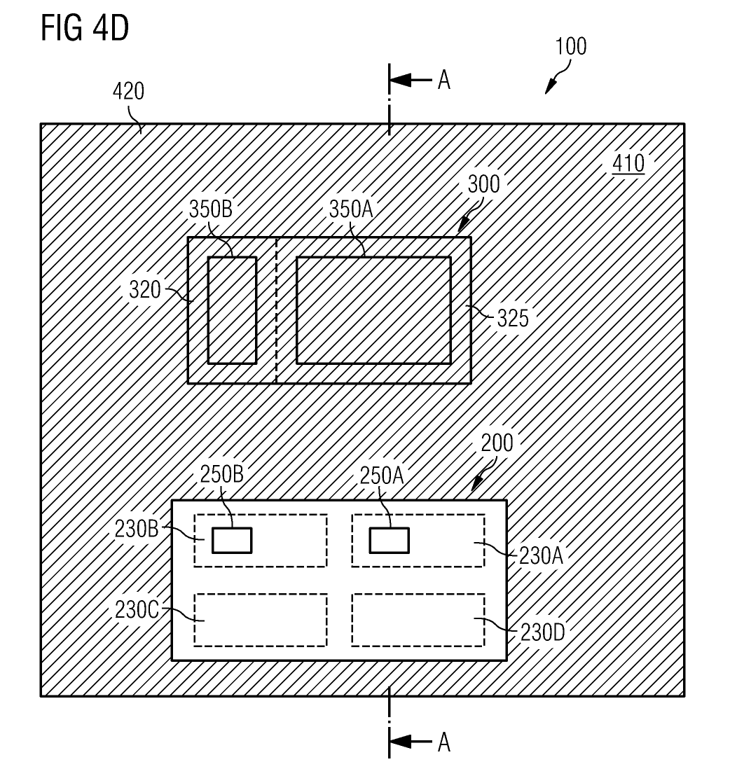

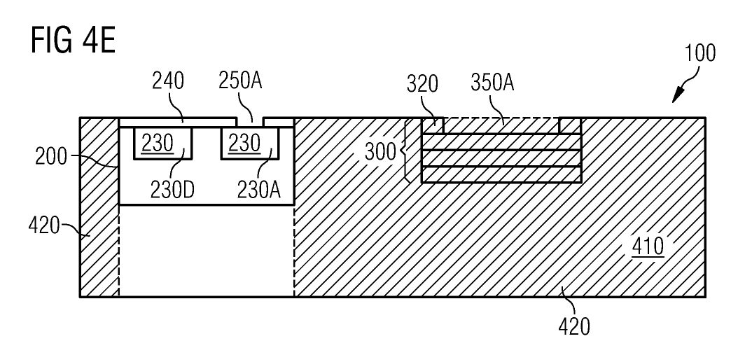

FIGS. 4A,B,C illustrate a semiconductor structure 100 which is an embodiment of a partially completed semiconductor device of the present invention. FIG. 4A is a top view of the structure 100 while FIG. 4B is a cross sectional view of structure 100 through AA and FIG. 4C is a cross-sectional view through BB. The structure 100 includes a semiconductor chip 200 (which may also be referred to as a die), a plate assembly 300 and a support structure 410. The chip 200 and the plate assembly 300 are supported by and embedded within the support structure 410. A top view of the semiconductor chip 200 is also shown in FIG. 1A while a cross sectional view of chip 200 through the cross section AA is shown in FIG. 1B. The plate assembly 300 is also shown in FIG. 2.

FIG. 1A shows a top view of a semiconductor chip 200. FIG. 1B is a cross sectional view through the cross section AA. Referring to FIG. 1B, the semiconductor chip or die 200 includes a bottom surface 202B and sidewall surfaces 202S. The chip 200 includes a top or active surface which is opposite the bottom surface 202B. The chip 200 further includes a final metal layer 230 which, in one or more embodiments, may be proximate to the top or active surface of the chip. A passivation layer 240 may be formed over the final metal layer 230. It is noted that the final metal layer of the semiconductor chip may also be referred to in the art as the top metal layer.

While not shown, the chip 200 typically includes a substrate which may be adjacent or proximate to its bottom surface. Likewise, the chip may further include additional metal layers, additional dielectric layers (such as interlevel dielectric layers), components such as diodes and transistors, logic circuits, memory circuits, etc. The final metal layer may be electrically coupled to the chip substrate as well as to devices that are formed in the chip substrate.

The final metal layer 230 of the chip 200 may comprise any metallic material. The final metal layer may be any pure metal or metal alloy. The final metal layer may include one or more elements such as Cu, Al, W, Au, or Ag. In one or more embodiments, the final metal layer may include the element C. Examples of metallic materials which may be used include, but are not limited to, pure copper, copper alloy, pure aluminum, aluminum alloy, pure tungsten, tungsten alloy, pure silver, silver alloy, pure gold, and gold alloy. The final metal layer may be used in combination with additional layers such as barriers, liners and/or cap layers comprising, for example, Ta, TaN, TaC, Ti, TiN, TiW, WN, WCN, CoWP, CoWB, NiMoP, Ru, Ni, Pd or combinations thereof.

The final metal layer may comprise one or more metal lines which may be referred to herein as final metal lines. In one or more embodiments, the final metal layer has at least two final metal lines. In an embodiment, each of the final metal lines of the final metal layer may be spacedly disposed from each other. In an embodiment, each of the final metal lines may be electrically isolated from each other.

In the embodiment shown in FIGS. 1A,B, the final metal layer 230 includes at least a first final metal line 230A, a second final metal line 230B, a third final metal line 210C and a fourth final metal line 230D. In one or more embodiments, at least one of the final metal lines may include one or more bonding pads (also referred to as contact pads). In one or more embodiments, each of the final metal lines may include one or more bonding pads.

Generally, the thickness of the final metal lines is not limited to any particular thickness. In one or more embodiments, each of the final metal lines 230A-D may have a thickness which is greater than about 250 nm (nanometers). In one or more embodiments, each of the final metal lines 230A-D may have a thickness which is greater than about 400 nm. In one or more embodiments, each of the final metal lines 230A-D may have a thickness which is greater than about 500 nm. In one or more embodiments, each of the final metal lines 230A-D may have a thickness which is greater than about 600 nm. In one or more embodiments, each of the final metal lines may have a thickness which is greater than about 1000 nm. While not shown in FIGS. 1A,B, the final metal lines may be electrically coupled to underlying metal lines and to devices that are built within the chip substrate.

The passivation layer 240 of chip 200 may be formed of any dielectric material such as an oxide, a nitride, an oxynitride, an imide or combinations thereof. The passivation layer 240 may, for example, comprise one or more dielectric layers such as an oxide layer, a nitride layer, an oxynitride layer, an imide layer, or combinations thereof. As an example, the passivation layer may comprise an oxide layer overlying a nitride layer. As another example, the passivation layer may comprise a nitride layer overlying an oxide layer. As another example, the passivation layer may comprise a nitride-oxide-nitride stack (that is, a nitride layer overlying an oxide layer overlying another nitride layer) As another example, the passivation layer may comprise an oxide-nitride-oxide stack. In one or more embodiments, it is possible that the passivation layer 240 be formed of a high-K dielectric material. In one or more embodiments, the high-K material may have a dielectric constant greater than that of silicon dioxide. In one or more embodiments, the high-K material may have a dielectric constant greater than 3.9.

In one or more embodiments, the thickness of the oxide layer and/or the thickness of the nitride layer may be less than about 1000 nm (nanometer). In one or more embodiments, the thickness of the oxide layer and/or nitride layer may be less than about 500 nm. In one or more embodiments, the thickness of the oxide layer and/or the thickness of the nitride layer may be less than about 250 nm. In one or more embodiments, the thickness of the oxide layer and/or the thickness of the nitride layer may be less than about 200 nm. In one or more embodiments, the thickness of the oxide layer and/or the thickness of the nitride layer may be less than about 150 nm. In one or more embodiments, the thickness of the oxide layer and/or the thickness of the nitride layer may be less than about 100 nm. In one or more embodiments, the thickness of the oxide layer and/or the thickness of the nitride layer may be less than about 50 nm. In one or more embodiments, the thickness of the oxide layer and/or the thickness of the nitride layer may be less than about 25 nm. In one or more embodiments, the thickness of the oxide layer and/or the thickness of the nitride layer may be greater than about 15 nm. In one or more embodiments, the thickness of the oxide layer and/or the thickness of the nitride layer may be greater than about 30 nm.

In one or more embodiments, the thickness of the passivation layer 240 may be less than about 1000 nm. In one or more embodiments, the thickness of the passivation layer 240 may be less than about 500 nm. In one or more embodiments, the thickness of the passivation layer 240 may be less than about 250 nm. In one or more embodiments, the thickness of the passivation layer 240 may be less than about 150 nm. In one or more embodiments, the thickness of the passivation layer 240 may be less than about 100 nm. In one or more embodiments, the thickness of the passivation layer 240 may be less than about 50 nm. In one or more embodiments, the thickness of the passivation layer 240 may be less than about 25 nm.

In the embodiment of the chip 200 shown in FIGS. 1A,B, openings 250A and 250B are formed through the passivation layer 240 so as to expose the second final metal lines 230A and 230B, respectively, of the final metal layer 230. The openings 250A and 250B may each be in the form of a hole and may be referred to as via openings. The openings 250A and 250B provide for future electrical coupling of the first final metal line 230A and the second final metal line 230B to, for example, redistribution layers. The openings 250A and 250B may be formed by a wet etch process or a dry etch process.

FIG. 2A shows a top view of a plate assembly 300. FIG. 2B shows a lateral cross sectional view through the cross section CC. Referring to FIG. 2B, the plate assembly 300 includes an optional base 310. The base 310 may comprise a dielectric material. Any dielectric material may be used. The dielectric material may comprise, for example, an oxide, a nitride, an oxynitride, an imide or combinations thereof. The base 310 may comprise a quartz material. The base may comprise an undoped silicon or a doped silicon material. The base may comprise GaAs. The base may comprise a polymer. The base may comprise an epoxy. In one or more embodiments, the base may be formed of one or more of the above mentioned materials. In one or more embodiments, the base may be formed as a combination of two or more of the above mentioned materials.

The plate assembly 300 further includes a conductive layer 320 that may be disposed over the base 310. The conductive layer 320 may be formed from any conductive material. The conductive material may be a metallic material such as a pure metal or a metal alloy. For example, the conductive layer 320 may include one or more of the elements Cu, Al, W, Au, or Ag. The conductive layer 320 may be formed of pure copper, copper alloy, pure aluminum, aluminum alloy, pure tungsten, tungsten alloy, pure silver, silver alloy, pure gold or gold alloy. The conductive material may be non-metallic. For example, the conductive material may be a doped polysilicon. The conductive material may be a conductive polymer. In an embodiment, the conductive layer 320 may consist essentially of a metallic material.

The conductive layer 320 may be formed, for example, by one or more of the techniques such as sputtering, plating, evaporation, CVD, atomic layer deposition followed by patterning (which may be lithography plus etching) steps or alternatively patterned plating or any damascene technology. The conductive layer 320 serves as a lower conductive plate for a capacitor. It is noted that as used herein, the term “plate” may have any shape and does not have to be flat. In one embodiment, a plate may be substantially flat.

In another embodiment, it is possible that a barrier material be placed between the conductive layer 320 and the base 310. The barrier material may include one or more of the materials Ta, TaN, Ti, TiN, TiW, WN, WCN.

The plate assembly 300 further includes a dielectric layer 330 disposed over the conductive interconnect 320. The dielectric layer 330 serves as the capacitor dielectric. The dielectric layer 330 may be any dielectric material. For example, the dielectric material 330 may be an oxide (such as silicon oxide), a nitride (such as silicon nitride), an oxynitride, an imide, a polyimide, a photoimide, a BCB (Benzo-cyclo-butene), etc. The dielectric layer 330 may include a high-k material such as Al₂O₃, Ta₂O₅, HfO₂, HfₓSi_{y}O_{z} ZrO₂, TiO₂ Nb₂O₅, TiTaO, TiSiO₄, TaZrO BST, STO or PZT. The dielectric layer 330 may be a combination of different dielectric materials. The dielectric layer may be a laminated layer stack such as Al₂O₃/HfO₂/Al₂O₃, Al₂O₃/Ta₂O₅/Al₂O₃, HfO₂/Ta₂O₅/HfO₂ or other combinations.

After the dielectric layer 330 is formed, a protective layer 340 may be formed over the dielectric layer 330. The protective layer 340 may be formed of any dielectric material. For example, the protective layer may be formed of an oxide, a nitride an oxynitride, a imide, a polyimide, a photoimide , a BCB, an epoxy or any other dielectric polymer material. Alternately, it is possible to use a thicker dielectric layer as both the capacitor dielectric and a protective layer (for example, a lower portion used as the capacitor dielectric and an upper portion used as a protective layer).

A first opening 350A may then be formed through the protective layer 340 to expose the dielectric layer 330. The first opening 350A may stop on or within the dielectric layer 330. A second opening 350B is formed through the protective layer 340 and through dielectric layer 330 so as to expose the conductive layer 320. The second opening 350B may be formed on or within the conductive layer 320. First opening 350A is spacedly disposed from the second opening 350B. In one or more embodiments, each of the openings 350A,B may be in the formed of a hole. The openings 350A,B provide for the possibility of electrically coupling a conductive redistribution layer to either the dielectric layer 330 (e.g. the capacitor dielectric) and/or to the conductive layer 320 (e.g. the capacitor plate).

FIG. 2C shows a cross sectional view of the plate assembly 300 through the cross section AA showing the opening 350A (that exposes a top surface of dielectric layer 330. Likewise, FIG. 2D shows a cross sectional view of the plate assembly 300 through the cross section BB showing the opening 350B (that exposes a top surface of conductive layer 320).

In the embodiment shown in FIGS. 4A through 4C, the chip 200 and the plate assembly 300 are both embedded within a support 410 (also referred to as a support structure or a support substrate). Referring to FIGS. 4B,C the chip 200 and the plate assembly 300 are embedded within the support 410 such that the support 410 contacts the bottom and side surfaces of the chip 200 and the plate assembly 300 but the support does not contact the top surfaces of either the chip or the plate assembly. In other embodiments of the invention, the chip 200 and/or the plate assembly 300 may be embedded within the support such that the support may also be formed over at least a portion of the top surface of the chip 200 and/or at least a portion of the top surface of the plate assembly 300. Likewise, in other embodiments, the chip and the plate assembly may be embedded within the support such that the support contacts the sides of the chip and/or the sides of the plate assembly but not the top or bottom surfaces of the chip and/or the plate assembly.

In one or more embodiments, the chip and/or the plate assembly may be at least partially embedded within the support. In one or more embodiments, the chip and/or the plate assembly may be partially embedded within the support. In one or more embodiments, the chip and/or the plate assembly may be totally embedded within the support.

In the embodiment shown in FIGS. 4A,B,C, the plate assembly 300 is laterally spacedly disposed (e.g., spacedly displaced) from the chip 200 such that there is some lateral distance or space between the plate assembly 300 and the chip 200. However, in another embodiment, it is possible that the plate assembly 300 be simply laterally disposed from the chip 200 which would thus include the possibility that the plate assembly may touch or abut the chip 200.

FIGS. 1A,B show a single semiconductor chip 200, however, a plurality of semiconductor chips 200 may be formed at the same time on a single semiconductor wafer. The semiconductor wafer may then be singulated or diced into individual or singulated semiconductor chips 200. Singulation or dicing may be done with, for example, a diamond saw or a laser (or by any other method such as a chemical method). Likewise, FIGS. 2A-D shows a single plate assembly 300. A plurality of plate assemblies 300 may also be formed on a different single wafer. This wafer too may then be singulated or diced into individual or singulated plate assemblies 300.

After forming a plurality of individual semiconductor chips (such as shown in FIGS. 1A,B) and a plurality of individual plate assemblies (such as shown in FIGS. 2A through 2D), the individual chips 200 as well as the individual plate assemblies 300 may be assembled together to form a reconfigured wafer. The reconfigured wafer may be formed by first doing a pre-assembly of at least one semiconductor chip 200 (such as shown in FIGS. 1A,B) and at least one plate assembly 300 (such as shown in FIGS. 2A-2D) together onto a carrier. In an embodiment, at least two chips and at least two plate assemblies are placed onto a carrier. In one or more embodiments, the pre-assembly process places a plurality of the individual semiconductor chips 200 in a regular fashion with a certain distance to each other. In one or more embodiments, this distance may be about 1 μm (micrometer or micron) to about several millimeter to each other. In one or more embodiments, the distance between the chips on the reconfiguration wafer may be greater than the distance on the original wafer.

In one or more embodiments, there may be a one to one ratio of chips and plate assemblies. In one or more embodiments, there may be more than one plate assembly per chip. In one or more embodiments, there may be more than one chip per plate assembly.

The pre-assembly process may be accomplished by placing the chips onto the surface of a carrier using a double sided adhesive tape. Next, one or more of the plate assemblies 300 may be positioned with their top surfaces (e.g., the surface having openings 350A,B) facing down on the carrier in the neighborhood of each of the chips also with the use of the tape. In one or more embodiments, one or more of the plate assemblies 300 may be placed adjacent to or proximate to a corresponding semiconductor chip 200. In one or more embodiments, the plate assemblies are spacedly disposed from the chips. In one or more embodiments, it is possible that the plate assemblies may touch the chips.

Hence, in one or more embodiments of the invention, the chips and the plate assemblies may be placed face down onto the tape. For example, the openings 250A and 250B of the chip 200 as well as the openings 350A and 250B of the plate assembly face toward the tape. The chip bottom and assembly bottom point away from the tape.

After placing the semiconductor chips 200 and the corresponding plate assemblies 300 onto a tape, the chips and assemblies are at least partially embedded within a support structure. This may be done in various ways. For example, the tape, the chips and the plate assemblies may be placed within a molding chamber, which is then filled with a liquid molding compound. In one or more embodiments, the molding compound may comprise a dielectric material. In one or more embodiments, the molding compound may consist essentially of a dielectric material. In one or more embodiments, the molding compound may comprise one or more of a variety of materials such as a plastic, polyimide, an epoxy based material or a BCB (Benzo-cyclo-butene). In one or more embodiments, the molding compound may have a low coefficient of thermal expansion (CTE) or a CTE that matches that of the semiconductor chip (which may comprise a silicon material). The molding compound fills in the spaces between the chips and the assemblies and may additionally be poured to a level which is above the bottom surfaces of the chips and/or the bottom surfaces of the plate assemblies.

After a molding compound has been used, an application of heat and/or pressure may then be used to harden the resin and build a planar assembly of a molded wafer with the embedded chips and plate assemblies. The molded wafer may then be removed from the carrier plate and the tape may be peeled away from the molded reconfigured wafer. The molding compound forms the support structure (also referred to as the support substrate or the support) for the reconfigured wafer.

In one or more embodiments, the molding compound may contact the side surfaces and the bottom surfaces of the chips and the plate assemblies without contacting the top surfaces. After the tape is removed, the top surfaces of the semiconductor chips and the plate assemblies are revealed to be exposed through the top surface of the support substrate.

In another embodiment, it is possible that the molding compound is only formed about the side surfaces of the chips and/or plate assemblies without contacting either the top or bottom surfaces. Also, in another embodiment it is possible that the molding compound is formed over at least a portion of the top surfaces of the chips and/or the plate assemblies.

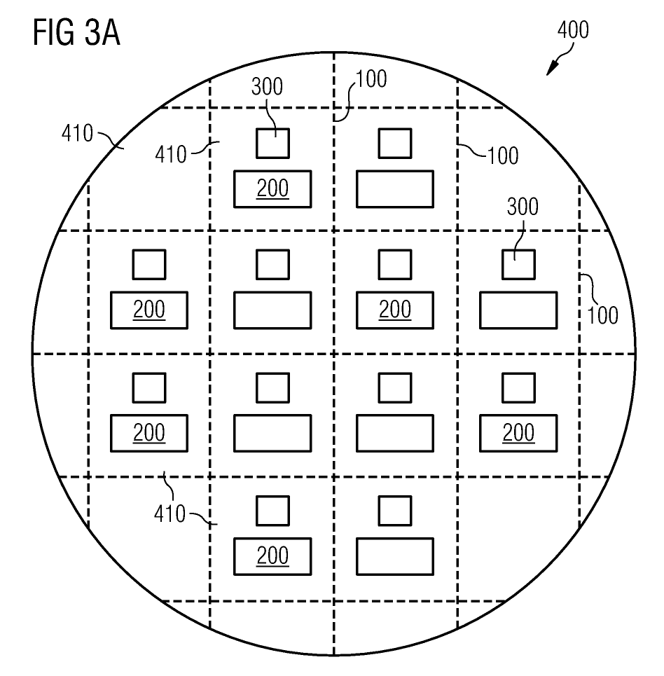

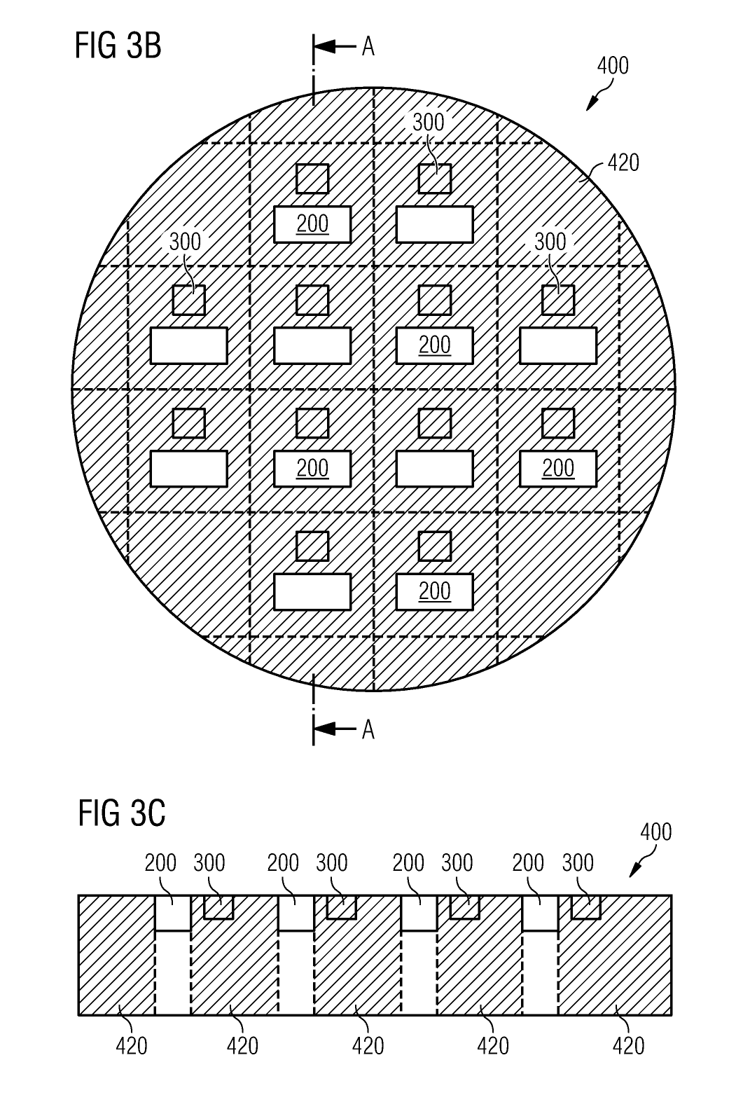

FIG. 3A shows a top view of an embodiment of a reconfigured wafer 400 that includes chips 200 and plate assemblies 300 embedded and supported within a support 410. The wafer 400 includes a plurality of structures 100. Each structure 100 represents an embodiment of an individual partially completed or completed semiconductor device or integrated circuit. Each of the structures 100 includes a semiconductor chip 200 and a plate assembly 300. In the embodiment shown in FIG. 3A, the average distance between the chips 200 in the reconfigured wafer 400 is larger than the average distance between the chips in the original wafer. Referring to FIG. 3A, it is seen that the lateral dimensions of the reconfigured wafer 400 extend beyond the lateral dimensions of the chips 200. The portion of the wafer 400 that is laterally outside the lateral boundaries of the chips 200 is referred to as the fan-out region of the reconfigured wafer 400.

FIG. 3B shows a top view of the fan-out region 420 of the reconfigured wafer 400. The fan-out region 420 is shown as the hatched area. The fan-out region 420 of the wafer extends to the edge of the wafer. FIG. 3C shows a cross sectional view of the wafer 400 through AA. FIG. 3C shows a cross sectional view of the fan-out region of the wafer 400. From FIGS. 3B and 3C, it is seen that the plate assemblies 300, being laterally disposed (or laterally spacedly disposed) from the chips 200, are disposed within the fan-out region of the wafer 400.

FIGS. 4A,B,C show top and cross sectional views of a structure 100 that includes a semiconductor chip 200 and an plate assembly 300 embedded or disposed within a support structure 410. FIG. 4A shows a top view of the structure 100. FIG. 4B shows a cross sectional view of FIG. 4A through the cross section AA. FIG. 4C shows a cross sectional view of FIG. 4A through the cross section BB. It is understood that the structure 100 shown in FIGS. 4A,B,C represents a portion of the reconfigured wafer 400 and that it represents one of a plurality of substantially identical structures 100 which are part of the reconfigured wafer 400 shown in FIG. 3A.

Referring to FIGS. 4A,B,C it is seen that the lateral boundary of the structure 100 extend beyond the lateral boundary of the chip 200. The portion of structure 100 that is laterally outside the lateral boundary of the chip 200 is the fan-out region of the structure 100. FIG. 4D shows a top view of the fan-out region 420 of the structure 100. FIG. 4E shows a cross sectional view of the fan-out region 420 of the structure 100 through AA. The fan-out region 420 is shown as the hatched region. It is noted that the fan-out region of the structure is laterally outside the lateral boundary of the chip. The fan-out region may extend lower than the bottom surface of the chip or it may extend higher than the top surface of the chip.

From FIGS. 4D and 4E it is seen that the plate assembly 300 is disposed outside the lateral boundary of the chip. It is embedded within the support 410 and lies within the fan-out region of structure 100.

In the embodiment shown in FIGS. 4A through 4E, the plate assembly 300 is laterally spacedly disposed from the lateral boundary of the chip 200. In this case, there is some positive distance or space between the plate assembly 300 and the lateral boundary of the chip 200. It is also possible, in another embodiment, that the plate assembly 300 touches a side of the chip 200. Hence, more generally, the plate assembly 300 may be laterally disposed from the chip 200 which includes the embodiment “laterally spacedly disposed” where there is some space between the assembly 300 and the chip 200 as well as the embodiment where there is no space between the assembly 300 and the chip 200 (for example, where the chip touches the plate assembly 300).

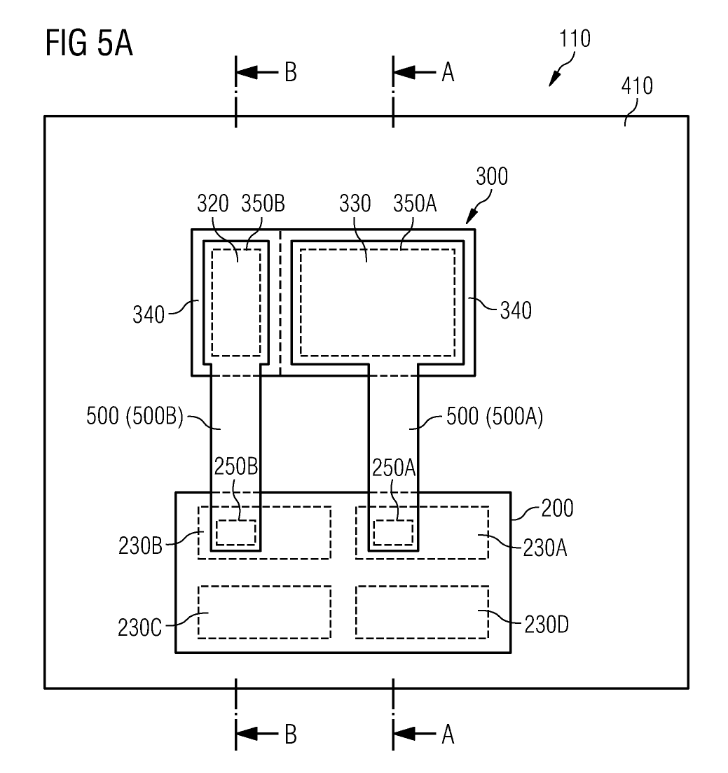

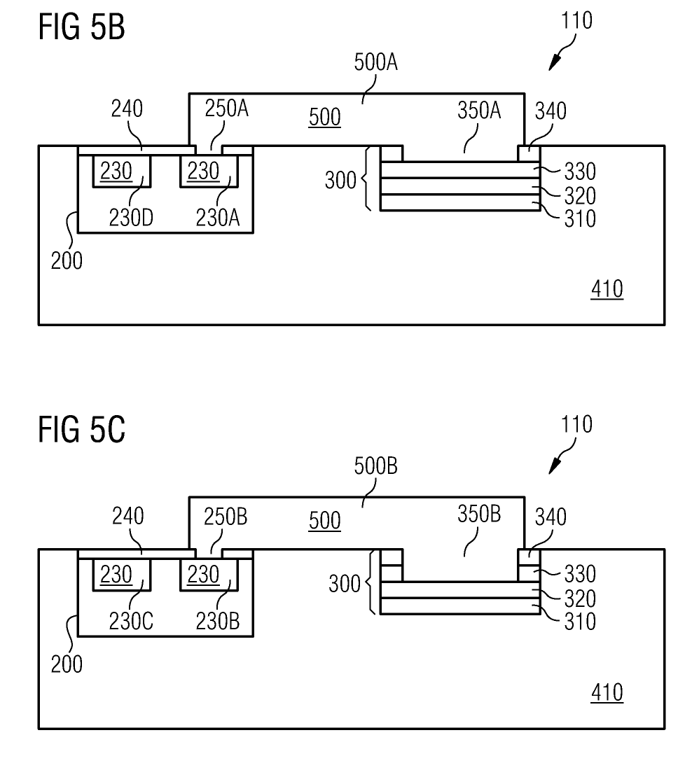

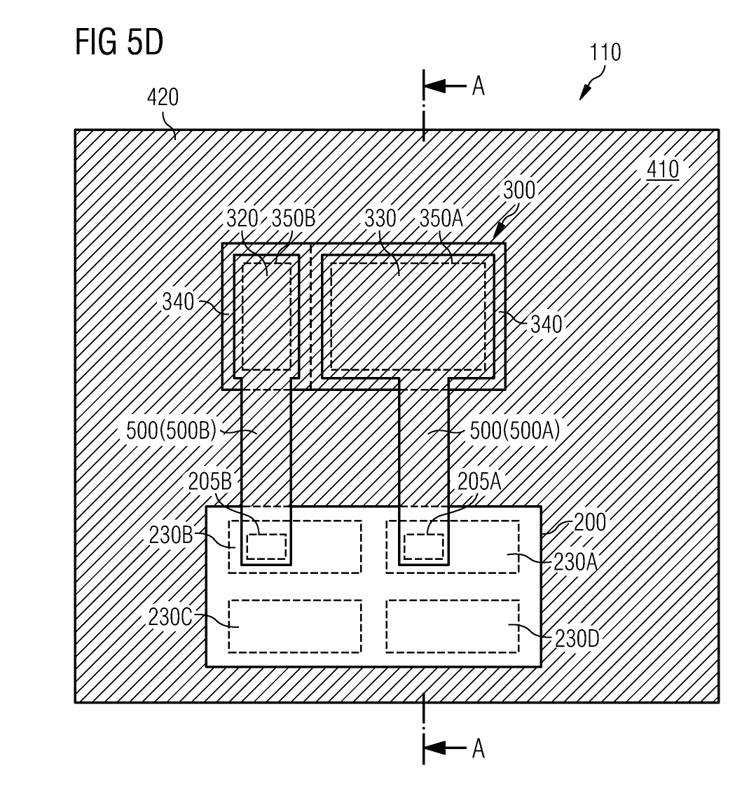

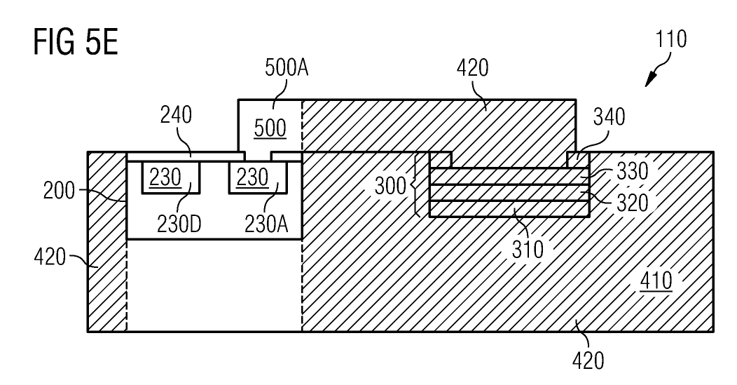

Referring to FIGS. 5A,B,C (with FIG. 5A being a top view, FIG. 5B being a corresponding cross sectional view through AA, and FIG. 5C being a corresponding cross sectional view through BB), a conductive redistribution layer 500 is formed over the structure 100 from FIGS. 4A-E (4A through 4E) to form the structure 110 in FIGS. 5A,B,C. The redistribution layer 500 comprises a first conductive portion 500A and a second conductive portion 500B. A cross sectional view of structure 110 through the cross section AA is shown in FIG. 5B. A cross sectional view of the structure 110 through the cross section BB is shown in FIG. 5C.

In an embodiment, a redistribution layer may be a single continuous conductive layer. In another embodiment, a redistribution layer may include a plurality of conductive portions. In an embodiment, two or more of the conductive portions may be spacedly disposed from each another. In an embodiment, two or more of the conductive portions may be electrically isolated from one another.

In one or more embodiments, each conductive portion of the redistribution layer may be a conductive layer which may form a conductive pathway. A conductive portion of the redistribution layer may have any shape. For example, it may be straight or curved. It may be star shaped (for example, fingers radiating from a central location). In one or more embodiments, the conductive portions of a redistribution layer may be conductive traces.

Generally, the redistribution layer may be formed of any conductive material. In one or more embodiments, the redistribution layer may comprise a metallic material. The metallic material may be a pure metal or a metal alloy. The metallic material may include one or more of the elements Cu, Al, W, Ag or Au. In one or more embodiments, the metallic material may comprise the element C (carbon). Examples of materials include, but are not limited to, metallic copper, copper alloy, metallic aluminum, and aluminum alloy. In an embodiment, the redistribution layer may consist essentially of a metallic material. In an embodiment, it is possible that the redistribution layer be formed by a metallic plating process.

In one or more embodiments, the redistribution layer may be formed of a non-metallic material such as a doped polysilicon or a conductive polymer. In one or more embodiments, the redistribution layer may, for example, be at least 1 μm (micron) thick and/or at least 1 μm (micron) wide. In one or more embodiments, the redistribution layer may, for example, be at least 2 microns thick and/or at least 2 microns wide.

The redistribution layer may, for example, be useful in distributing electrical signals to various portions of the semiconductor wafer, structure or device. The electrical signals may be in the form of electrical currents or voltages. In one or more embodiments, the redistribution layer may redistribute electrical signals to other positions that overlie the semiconductor chip. In one or more embodiments, the redistribution layer may redistribute electrical signals to positions that extend beyond the lateral boundaries of the chip. Hence, the redistribution layer may redistribute electrical signals to the fan-out region of the wafer, structure or device. Hence, in one or more embodiments, at least a portion of the redistribution layer may extend into the fan-out region of the wafer, structure or device.

In one or more embodiments of the invention, conductive balls (such as metallic balls or solder balls) may be electrically coupled to the conductive portions (such as to ends or termination points of the conductive portions). The conductive balls may be used to electrically couple the structure to, for example, a printed circuit board or a BGA-substrate. In one or more embodiments, the resulting wafer, structures or semiconductor devices may be formed as a wafer level ball package.

Referring again to FIGS. 5A,B,C, the redistribution layer 500 includes a first conductive portion 500A and a second conductive portion 500B. First conductive portion 500A and second conductive portion 500B are spacedly disposed from each other.

Referring to FIGS. 5A and 5B, it is seen that one end of the first conductive portion 500A is disposed within the opening 250A and is electrically coupled to the final metal line 230A. The opposite end of first conductive portion 500A is disposed within the opening 350A of protective dielectric layer 340. Hence, at part of the conductive portion 500A overlies the dielectric layer 330 and also overlies the first conductive layer 320. In an embodiment, the conductive portion 500A may be in direct contact with the dielectric layer 340. In the embodiment shown in FIG. 500A a part of the conductive portion 500A extends outside of the lateral boundary of the chip 200. In the embodiment shown, a part of the conductive portion 500A extends into the fan-out out region of the structure 110. In one or more embodiments, at least a part of the conductive portion 500A may extend into the fan-out region of the structure 110.

Referring to FIGS. 5A and 5C, it is seen that one end of second conductive portion 500B is disposed within the opening 250B and is electrically coupled to the final metal line 230B. The opposite end of second conductive portion 500B is disposed within the opening 350B (which has been formed through the protective dielectric layer 340 and the dielectric layer 330) so as to overlie and make electrical contact with the conductive layer 320.

Referring to FIG. 5B, the conductive layer 320, the dielectric layer 330 and at least a part of the first conductive portion 500A form a capacitor or capacitive element. Referring to FIG. 5B, at least a part of the first conductive portion 500A forms an upper conductive plate for the capacitor. In an embodiment, the upper conductive plate may be that part of the first conductive portion 500A that is proximate to the dielectric layer 330. Also, at least a part of the first conductive portion 500A electrically couples the upper conductive plate of the capacitor to the first final metal layer 230A of the chip 200. The dielectric layer 330 forms a dielectric layer for the capacitor.

Referring to FIG. 5B, it is seen that the conductive layer 320 forms a lower conductive plate of the capacitor. Referring to FIGS. 5A and 5C, it is seen that the second conductive portion 500B electrically couples the lower conductive plate 320 of the capacitor or capacitive element to the second final metal line 230B.

Generally, the conductive layer 320 as well as the redistribution layer may be formed of any conductive material. In one or more embodiments, the conductive layer 320 as well as the first portion 500A of the redistribution layer may both consist essentially of a metallic material. In this case, both the lower and upper capacitor plate consist essentially of a metallic material. In this case, the capacitor may be an MIM (metal-insulator-metal) capacitor. The metallic material may, for example, be a pure metal or a metal alloy. One or more additional layers may, of course, be disposed between the conductive portion 500A and the dielectric layer 330, between the dielectric layer 330 and the conductive layer 320, or between the conductive layer 320 and the conductive portion 500B.

FIG. 5D is the top view of structure 110 from FIG. 5A which now also shows the fan-out region 420 (the cross hatched area) of the structure 110. The fan-out region of the structure 110 is that portion which is outside the lateral boundary of the chip 200. The fan-out region 420 is also seen in the cross sectional view of FIG. 5E (which is a cross section through AA of FIG. 5D). As seen in FIG. 5E, the fan-out region 420 of the structure 110 may extend higher than the top surface of the chip 200 or it may extend lower than the bottom surface of the chip 200.

The FIGS. 5D and 5E show that the capacitor formed by the conductive layer 320, dielectric layer 330 and first conductive portion 500A is disposed within the fan-out region of the structure 110 and is disposed outside the lateral boundary of the chip 200. Placing the capacitor outside the lateral boundary of the chip may improve the Q-factor of the capacitor since there may be less parasitic coupling to the silicon wafer and the circuitry on the chip.

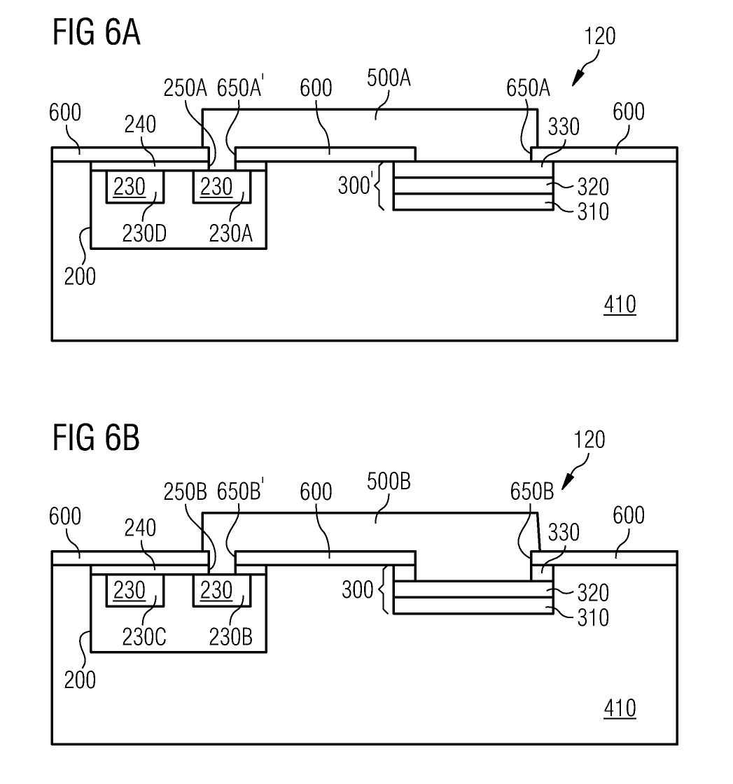

FIGS. 6A and 6B show cross sectional views of a structure 120 which is another embodiment of the invention. FIG. 6A shows the cross section through the lines 230A, 230D. FIG. 6B shows the cross section through the lines 230B, 230C. In the embodiment shown in FIGS. 6A,B, the structure 120 includes a plate assembly 300′. The plate assembly 300′ is formed without a protective dielectric layer. The plate assembly 300′ comprises a base 310, a conductive layer 320, and a dielectric layer 330. A dielectric protection layer 600 is disposed over the entire structure after the chip 200 and plate assembly 300′ are embedded within the support 410.

Hence, after the reconfigured wafer is formed (such as by a molding process), a protective dielectric layer 600 (for example, an oxide, a nitride, an oxynitride, a polyimide, a BCB, etc.) may be deposited over the structure. Hence, the protective dielectric layer 600 may be formed over the semiconductor chip 200, the plate assembly 300′ and the support 410. Referring to FIG. 6A, in this protective dielectric layer 600, an opening 650A may be formed to expose the dielectric 330 and an opening 650A′ may be formed to expose the first final metal line 230A. Referring to FIG. 6B, an opening 650B may be formed to expose the conductive layer 320 and an opening 650B′ may be formed to expose the second final metal line 230B.

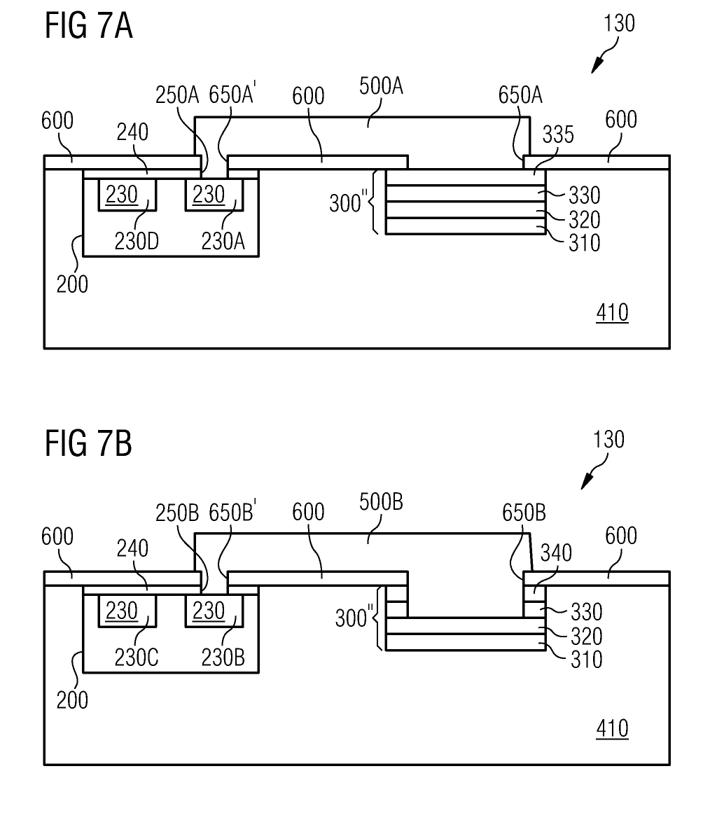

FIGS. 7A and 7B show cross sectional views of a structure 130 which is another embodiment of the invention. FIG. 7A corresponds to the cross section through the lines 230A, 230D. FIG. 7B corresponds to the cross section through lines 230B, 230C. The structure 130 includes a plate assembly 300″. Referring to FIG. 7A, the plate assembly 300″ includes a base 310, a lower conductive layer 320, a dielectric layer 330 and an upper conductive layer 335. In this embodiment, the lower conductive layer 320 forms a lower conductive plate for the capacitor (the lower capacitor plate), the dielectric layer 320 forms a dielectric layer for the capacitor (the capacitor dielectric), while the upper conductive layer 335 forms the upper conductive plate for the capacitor (the upper capacitor plate). The first conductive portion 500A electrically couples the upper conductive plate 335 to the first final metal layer 230A.

Referring to FIG. 7B, it is seen that an additional protective dielectric layer 340 may replace the upper conductive layer 335 over a portion of the plate assembly so that the second conductive portion 500B makes electrical contact only with the lower conductive plate 320. The embodiment shown in FIGS. 7A,B illustrates that both conductive plates of the capacitor may be incorporated within the plate assembly 300″ that is embedded within the support 410. Hence, the lower conductive plate of the capacitor, the dielectric layer of the capacitor as well as the upper conductive plate of the capacitor may all be formed as part of a plate assembly and this plate assembly may be at least partially embedded within the support.

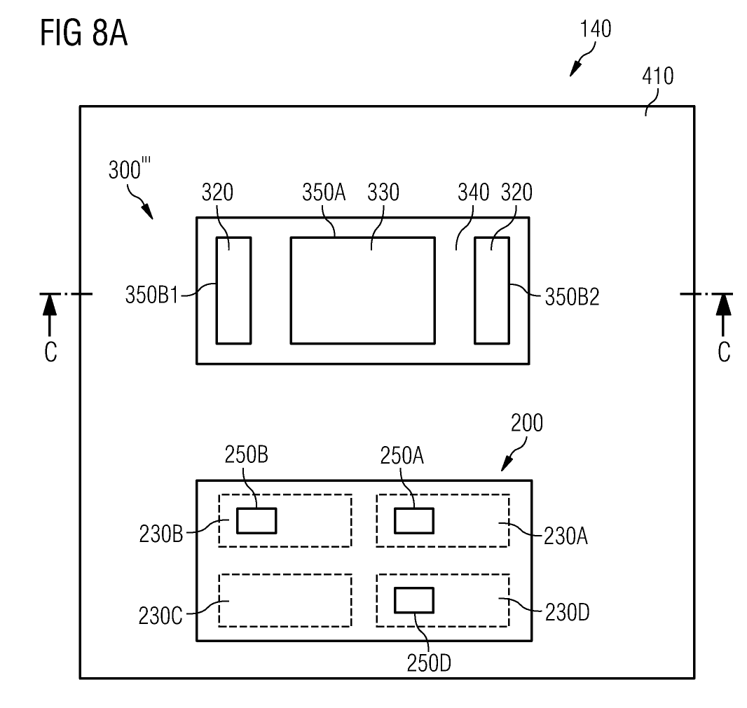

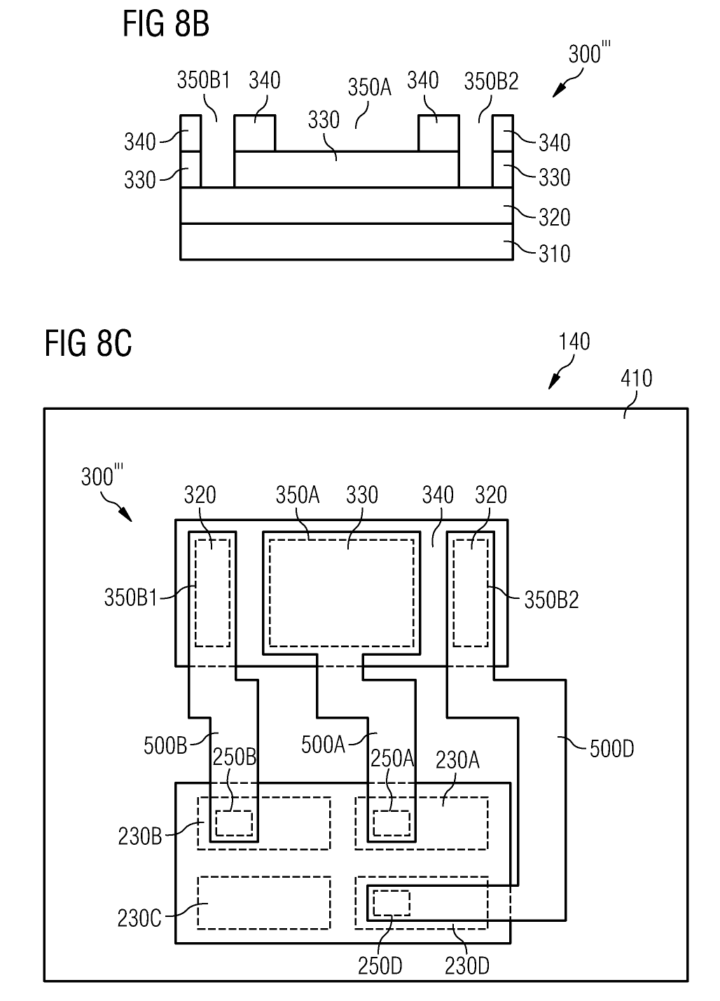

FIGS. 8A and 8C shows a structure 140 which is another embodiment of the present invention. The structure 140 comprises a chip 200 as well as a capacitive assembly 300′″. The capacitive assembly 300′″ includes a base 310, a lower conductive layer 320 formed over the base 310, and a capacitor dielectric layer 330 formed the capacitor dielectric layer 330. The lower conductive layer 320 is used as a lower conductive plate for a capacitor while the dielectric layer is used as a dielectric layer of the capacitor. The capacitive assembly 300′″ further includes a protective dielectric layer 340. An opening 350A is formed through the protective dielectric layer to expose the capacitor dielectric layer 330. In this embodiment, two openings 350B1 and 350B2 are formed through both the protective dielectric layer 340 and the capacitor dielectric layer 330 to expose two spacedly disposed portions of the lower conductive layer 320. FIG. 8B shows a cross sectional view of the plate assembly 300′″ through the cross section CC.

Referring to FIG. 8C, in this embodiment, an additional conductive portion 500D is used to make an additional electrical coupling from the fourth final metal line 230D of chip 200 to the lower conductive layer 320 of the conductive assembly 300′″. The additional conductive portion 500D may also be part of a redistribution layer. The conductive portion 500A is electrically coupled between the final metal line 230A (through opening 250A) and the capacitor dielectric 330 (through opening 350A). The conductive portion 500B is electrically coupled between the final metal line 230B (though opening 250B) and the lower conductive layer 320 (through opening 350B1). Hence, in the embodiment shown in FIGS. 8A,B, The conductive portion 500D is electrically coupled between the final metal line 230D (through the opening 250D) and the lower conductive layer 320 (through the opening 350B2). The lower conductive layer 320 is electrically coupled to the final metal layer 230A and to the final metal layer 230D. The two final metal layers 230A,D may be electrically coupled together. In another embodiment, the two conductive portions 500B,D may be electrically coupled to the same final metal line.

It is noted that in one or more embodiments, the plate assembly may be formed without the use of a base. For example, referring to FIG. 5C, the plate assembly 300 may be formed without the use of the base 310. Referring to FIG. 6A, the plate assembly 300′ may be formed without the base 310. Referring to FIG. 7A, the plate assembly 300″ may be formed without the base 310. Referring to FIG. 8B, the plate assembly 300′″ may be formed without the base 310.

It is also noted that in one or more embodiments, the plate assembly may be formed without the use of a capacitor dielectric layer. For example, the plate assembly may simply consist essentially of a lower capacitor plate. In such a case, the lower capacitor plate may be at least partially embedded within the support (for example, when the molding compound is used). A capacitor dielectric may later be formed over the lower capacitor plate to form a capacitor dielectric. The capacitor dielectric may be formed after the reconfiguration wafer is formed. A conductive layer such as a reconfiguration layer may then be formed over the capacitor dielectric to form an upper or top capacitor plate. In yet another embodiment, the plate assembly may consist essentially of a capacitor plate disposed over a base.

In yet another embodiment, it is also possible that a plurality of chips be at least partially embedded within a support to form a reconfiguration wafer. The capacitor may then be formed after the reconfiguration wafer is formed. Hence, it is possible that a first (e.g., lower or bottom) capacitor plate, a capacitor dielectric as well as a second (e.g. upper or top) capacitor plate be formed after the reconfiguration wafer is formed.

In one or more embodiments, in a downstream processing step, after the individual structures on a reconfigured wafer are completed, the wafer may be singulated to form individual and separated semiconductor devices. The singulation process may be performed, for example, by mechanical means such as with the use of a saw, thermal means such as with the use of a laser, by chemical means or by any other means.

An embodiment of the invention is a semiconductor structure, comprising: a semiconductor chip at least partially embedded within a support; and a capacitor electrically coupled to the chip, the capacitor disposed outside the lateral boundary of the chip.

An embodiment of the invention is a semiconductor structure, comprising: a semiconductor chip at least partially embedded within a support; a first conductive layer at least partially embedded within the support outside the lateral boundary of the chip, the first conductive layer being electrically coupled to the chip; a second conductive layer electrically coupled to the chip, at least a portion of second conductive layer disposed over the first conductive layer; and a dielectric material between the first conductive layer and second conductive layer.

An embodiment of the invention is a method of forming a semiconductor structure, comprising: providing a wafer, the wafer comprising at least two semiconductor chips; dicing the wafer into individual chips; and forming a structure by a method comprising the step of at least partially embedding a plurality of the individual chips in a support, the structure including a plurality of capacitors, each of the capacitors at least partially embedded within the support outside the lateral boundaries of the chips, the capacitors being electrically coupled to the chips.

An embodiment of the invention is a method of forming a semiconductor structure, comprising: dicing a wafer into at least two individual chips; at least partially embedding a plurality of the chips in a support; and forming a plurality of capacitors, each of the capacitors being at least partially embedded within the support outside the lateral boundaries of the chips.

An embodiment of the invention is a method of forming a semiconductor structure, comprising: dicing a wafer into at least two individual chips; providing a plurality of individual conductive plates; at least partially embedding a plurality of the chips in a support; at least partially embedded a plurality of the plates in a support, the plates being disposed outside the lateral boundaries of the chips; forming a dielectric material over each of the plates; and forming a redistribution layer, at least a portion of the redistribution layer formed over the dielectric material.

It is to be understood that the disclosure set forth herein is presented in the form of detailed embodiments described for the purpose of making a full and complete disclosure of the present invention, and that such details are not to be interpreted as limiting the true scope of this invention as set forth and defined in the appended claims.

What is claimed is:

1. A semiconductor structure, comprising:
a semiconductor chip at least partially embedded within a support; and
a capacitor electrically coupled to said chip, said capacitor disposed outside the lateral boundary of said chip.

2. The structure of claim 1, wherein said capacitor is at least partially embedded within said support.

3. The structure of claim 1, wherein said capacitor is electrically coupled to said chip by at least a portion of a conductive redistribution layer.

4. The structure of claim 1, wherein said capacitor comprises a capacitor plate, said capacitor plate being part of a conductive redistribution layer.

5. The structure of claim 1, further comprising a conductive redistribution layer, said redistribution layer including a first portion and a second portion spacedly disposed from said first portion, said first portion having a first part forming a first capacitor plate of said capacitor, said first portion having a second part electrically coupling said first capacitor plate to said chip, said second portion electrically coupling a second capacitor plate of said capacitor to said chip.

6. The structure of claim 1, wherein said capacitor has a first capacitor plate electrically coupled to a first final metal line of said chip and a second capacitor plate electrically coupled to a second final metal line of said chip.

7. The structure of claim 1, wherein said support comprises a molding compound.

8. The structure of claim 1, wherein said structure is a wafer level ball package.

9. A semiconductor structure, comprising:
a semiconductor chip at least partially embedded within a support;
a first conductive layer at least partially embedded within said support outside the lateral boundary of said chip, said first conductive layer being electrically coupled to said chip;
a second conductive layer electrically coupled to said chip, at least a portion of second conductive layer disposed over said first conductive layer; and
a dielectric material between said first conductive layer and second conductive layer.

10. The structure of claim 9, wherein said second conductive layer is part of a conductive redistribution layer.

11. The structure of claim 10, wherein said redistribution layer comprises a metallic material.

12. The structure of claim 9, wherein said first conductive layer and said second conductive layer comprise a metallic material.

13. The structure of claim 9, wherein said dielectric material is at least partially embedded within said support.

14. The structure of claim 9, wherein said structure is a wafer level ball package.

15. A method of forming a semiconductor structure, comprising:
providing a wafer, said wafer comprising at least two semiconductor chips;
dicing said wafer into individual chips; and
forming a structure by a method comprising the step of at least partially embedding a plurality of said individual chips in a support, said structure including a plurality of capacitors, each of said capacitors at least partially embedded within said support outside the lateral boundaries of said chips, said capacitors being electrically coupled to said chips.

16. The method of claim 15, wherein said capacitors are electrically coupled to said chips by at least a portion of a redistribution layer overlying said support.

17. The method of claim 15, wherein said embedding step comprises the step of placing a molding compound about at least a portion of the sides of said chips.

18. A method of forming a semiconductor structure, comprising:
dicing a wafer into at least two individual chips;
at least partially embedding a plurality of said chips in a support; and
forming a plurality of capacitors, each of said capacitors being at least partially embedded within said support outside the lateral boundaries of said chips.

19. The method of claim 18, wherein said capacitors are electrically coupled to said chips.

20. The method of claim 19, wherein said capacitors are electrically coupled to said chips by at least a portion of a redistribution layer.

21. The method of claim 18, wherein said forming said capacitors step comprises the steps of:
providing a plurality of individual conductive plates;
a least partially embedding said plates in said support outside the lateral boundaries of said chips;
forming a dielectric layer over each of said plates; and
forming at least a portion of a redistribution layer over said dielectric layers.

22. The method of claim 21, wherein said dielectric layer are formed over said plates before said plates are embedded within said support.

23. A method of forming a semiconductor structure, comprising:
dicing a wafer into at least two individual chips;
providing a plurality of individual conductive plates;
at least partially embedding a plurality of said chips in a support;
at least partially embedded a plurality of said plates in a support, said plates being disposed outside the lateral boundaries of said chips;
forming a dielectric material over each of said plates; and
forming a redistribution layer, at least a portion of said redistribution layer formed over said dielectric material.

24. The method of claim 23, wherein said dielectric material is formed over said plates before said plates are at least partially embedded in said support.

25. The method of claim 23, wherein said redistribution layer comprises a conductive material.
